(19) United States
(12) Patent Application Publication
(10) Pub. No.: US 2024/0304673 A1
(43) Pub. Date: Sep. 12, 2024

(54) SILICON CARBIDE SEMICONDUCTOR DEVICE

(71) Applicant: FUJI ELECTRIC CO., LTD., Kawasaki-shi (JP)

(72) Inventor: Tomohiro MORIYA, Matsumoto-city (JP)

(73) Assignee: FUJI ELECTRIC CO., LTD., Kawasaki-shi (JP)

(21) Appl. No.: 18/426,507

(22) Filed: Jan. 30, 2024

(30) Foreign Application Priority Data
Mar. 9, 2023 (JP) 2023-036567

(51) Int. Cl. H01L 29/16; H01L 23/528; H01L 29/78

(52) U.S. Cl. CPC H01L 29/1608; H01L 23/528; H01L 29/7811

(57) ABSTRACT

A silicon carbide semiconductor device includes: a drift layer of a first conductivity-type; a semiconductor region of a second conductivity-type provided on a top surface side of the drift layer in an intermediate part between an active part and an edge termination part; a first insulating film provided on a top surface of the semiconductor region; a wiring layer provided on a top surface of the first insulating film; a second insulating film provided on a top surface of the wiring layer; and a gate pad provided on a top surface of the second insulating film so as to be electrically connected to the wiring layer, wherein the semiconductor region includes a first region having a 4H structure overlapping with at least a part of the wiring layer in a depth direction, and a second region having a 3C structure provided on a top surface side of the first region.

### CROSS-REFERENCE TO RELATED APPLICATION

This application claims benefit of priority under 35 USC 119 based on Japanese Patent Application No. 2023-036567 filed on Mar. 9, 2023, the entire contents of which are incorporated by reference herein.

### BACKGROUND OF THE INVENTION

### 1. Field of the Invention

The present invention relates to silicon carbide (SiC) semiconductor devices.

### 2. Description of the Related Art

JP 2009-049198 A discloses a semiconductor device including an amorphous layer obtained by implantation of impurity ions into a silicon carbide substrate of hexagonal single crystals so as to be subjected to annealing to be recrystallized into silicon carbide of cubic single crystals.

WO 2017/042963 A1 discloses a semiconductor device including an n type epitaxially-grown layer grown on a first main surface of an n⁺-type SiC substrate including 4H—SiC, an n⁺-type source region formed in the n⁻ type epitaxially-grown layer, and an n⁺-type 3C—SiC region and a p⁺-type potential fixing region each formed in the n⁺-type source region, in which a barrier metal film is formed in contact with the n⁺-type 3C—SiC region and the p⁺-type potential fixing region, and a source wiring electrode is further formed on the barrier metal film.

The conventional silicon carbide semiconductor device has a configuration in which a wiring layer (a gate runner) including polysilicon is provided under a gate pad so as to be connected to each other via an opening of the insulating film provided in the top surface of the wiring layer. The wiring layer is provided on the top surface of a p-type semiconductor region with an insulating film interposed. The silicon carbide semiconductor device having such a configuration may cause damage to the insulating film located between the p-type semiconductor region and the wiring layer under the gate pad during the switching operation.

### SUMMARY OF THE INVENTION

In view of the foregoing problems, the present invention provides a silicon carbide semiconductor device having a configuration capable of avoiding damage to an insulating film under a gate pad during a switching operation.

An aspect of the present invention inheres in a silicon carbide semiconductor device including: a drift layer of a first conductivity-type including silicon carbide and provided from an active part including an active element to an edge termination part located at a circumference of the active part; a semiconductor region of a second conductivity-type including silicon carbide and provided on a top surface side of the drift layer in an intermediate part interposed between the active part and the edge termination part; a first insulating film provided on a top surface of the semiconductor region; a wiring layer provided on a top surface of the first insulating film; a second insulating film provided on a top surface of the wiring layer; and a gate pad provided on a top surface of the second insulating film so as to be electrically connected to the wiring layer via an opening provided in the second insulating film, wherein the semiconductor region includes a first region having a 4H structure overlapping with at least a part of the wiring layer in a depth direction, and a second region having a 3C structure provided on a top surface side of the first region.

### BRIEF DESCRIPTION OF THE DRAWINGS

FIG. 1 is a schematic plan view illustrating a silicon carbide semiconductor device according to a first embodiment;

FIG. 2 is a schematic cross-sectional view taken along line A-A′ in FIG. 1;

FIG. 3 is a schematic cross-sectional view illustrating a silicon carbide semiconductor device of a comparative example;

FIG. 4 is a schematic cross-sectional view illustrating the silicon carbide semiconductor device of the comparative example during a switching operation;

FIG. 5 is a schematic cross-sectional view illustrating the silicon carbide semiconductor device according to the first embodiment during a switching operation;

FIG. 6 is a schematic cross-sectional view illustrating a silicon carbide semiconductor device according to a second embodiment;

FIG. 7 is a schematic cross-sectional view illustrating a silicon carbide semiconductor device according to a third embodiment; and

FIG. 8 is a schematic cross-sectional view illustrating a silicon carbide semiconductor device according to a fourth embodiment.

### DETAILED DESCRIPTION

With reference to the drawings, first to fourth embodiments of the present invention will be described below.

In the drawings, the same or similar elements are indicated by the same or similar reference numerals, and overlapping explanations are not repeated. The drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions. The first to fourth embodiments described below merely illustrate schematically devices and methods for specifying and giving shapes to the technical idea of the present invention, and the span of the technical idea is not limited to materials, shapes, structures, and relative positions of elements described herein.

As used in the present specification, a source region of a metal-oxide-semiconductor field-effect transistor (MOSFET) is referred to as “one of the main regions (a first main region)” that can be used as an emitter region of an insulated gate bipolar transistor (IGBT). The “one of the main regions”, when provided in a thyristor such as a MOS controlled static induction thyristor (SI thyristor), can be used as a cathode region. A drain region of the MOS transistor is referred to as the “other one of the main regions (a second main region)” of the semiconductor device that can be used as a collector region in the IGBT or as an anode region in the thyristor. The term “main region”, when simply mentioned in the present specification, is referred to as either the first main region or the second main region that is determined as appropriate by the person skilled in the art.

Further, definitions of directions such as an up-and-down direction in the following description are merely definitions for convenience of understanding, and are not intended to limit the technical ideas of the present invention. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction. In addition, an “upper surface” may be read as “front surface”, and a “lower surface” may be read as “back surface”.

Further, in the following description, there is exemplified a case where a first conductivity-type is an n-type and a second conductivity-type is a p-type. However, the relationship of the conductivity types may be inverted to set the first conductivity-type to the p-type and the second conductivity-type to the n-type. Further, a semiconductor region denoted by the symbol “n” or “p” attached with “+” indicates that such semiconductor region has a relatively high impurity concentration or a relatively low specific resistance as compared to a semiconductor region denoted by the symbol “n” or “p” without “+”. A semiconductor region denoted by the symbol “n” or “p” attached with “−” indicates that such semiconductor region has a relatively low impurity concentration or a relatively high specific resistance as compared to a semiconductor region denoted by the symbol “n” or “p” without “−”. However, even when the semiconductor regions are denoted by the same reference symbols “n” and “n”, it is not indicated that the semiconductor regions have exactly the same impurity concentration or the same specific resistance.

In addition, a crystal polymorphism is present in SiC crystals, and main examples include 3C (3C—SiC) of a cubic crystal, and 4H (4H—SiC) and 6H (6H—SiC) of a hexagonal crystal. A bandgap at room temperature is reported that is 2.23 eV in 3C—SiC, 3.26 eV in 4H—SiC, and 3.02 eV in 6H—SiC. The following embodiments are illustrated with a case of mainly using 4H—SiC and 3C—SiC.

### First Embodiment

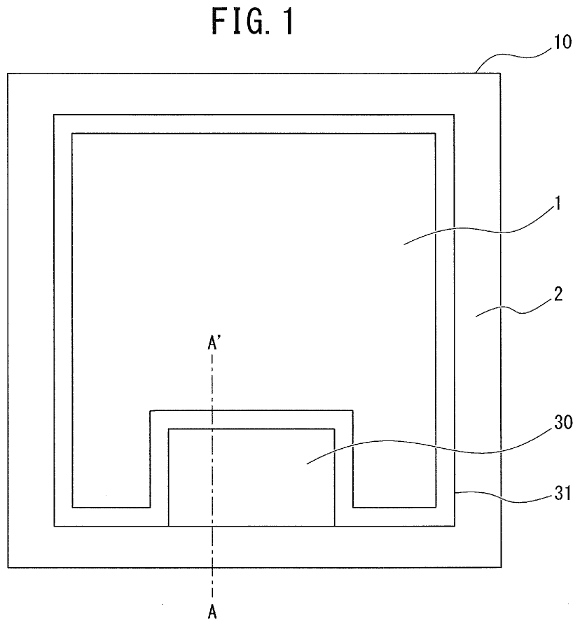

A silicon carbide semiconductor device according to a first embodiment includes an active part 1 and an edge termination part 2 provided in a semiconductor base-body (a semiconductor chip) 10 including SiC, as illustrated in FIG. 1. The active part 1 has a substantially rectangular planar shape arranged substantially in the middle of the semiconductor base-body 10. The active part 1 includes an active element (a switching element) that is a region through which a main current flows during an ON-state of the active element. The active element may be a vertical-type switching element, for example. The present embodiment is illustrated with a case in which the active element included in the active part 1 is a MOSFET having a trench gate structure.

The edge termination part 2 has a ring-shaped (frame-like) planar shape provided to surround the circumference of the active part 1. The edge termination part 2 is a region for relaxing an electric field on the top surface side of the semiconductor base-body 10 to keep the breakdown voltage.

A gate pad 30 is provided in a part between the active part 1 and the edge termination part 2. The gate pad 30 has a substantially rectangular planar shape. A wiring layer (a gate runner) 31 is electrically connected to the gate pad 30. The wiring layer 31 is provided to surround the circumference of the active part 1. The gate pad 30 is electrically connected to a gate electrode of the active element of the active part 1 via the wiring layer 31.

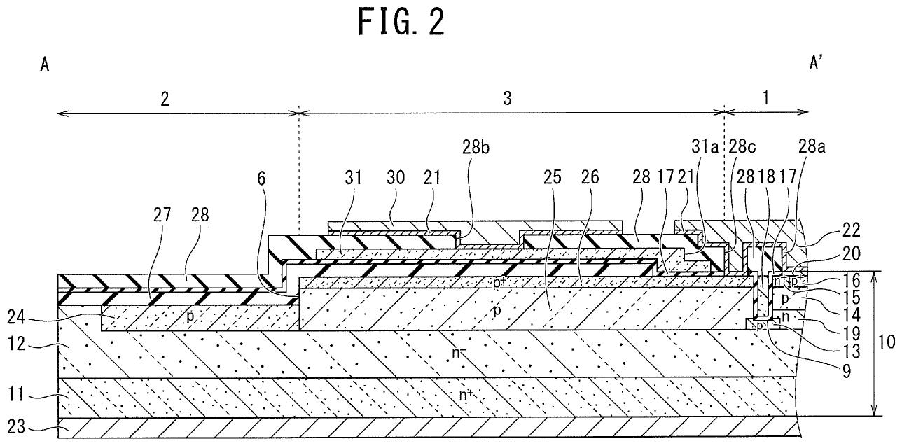

FIG. 2 is a cross-sectional view taken along line A-A′ in FIG. 1. As illustrated in FIG. 2, the silicon carbide semiconductor device according to the first embodiment includes the active part 1, the edge termination part 2 located on the outside of the active part 1, and an intermediate part 3 interposed between the active part 1 and the edge termination part 2. The intermediate part 3 is defined as a region including the gate pad 30 and arranged on the outside of a trench 9 located at the outermost circumference of the active part 1 and on the inside of a voltage blocking region 24 of the edge termination part 2.

A drift layer 12 of a first conductivity-type (n-type) is provided along the active part 1 and the edge termination part 2 across the intermediate part 3. The drift layer 12 is an epitaxially-grown layer including SiC such as 4H-SiC, for example. The drift layer 12 has an impurity concentration in a range of about 1×10¹⁵ cm⁻³ or greater and 5×10¹⁶ cm⁻³ or less, for example. The drift layer 12 has a thickness in a range of about one micrometer or greater and 100 micrometers or smaller, for example. The impurity concentration and the thickness can be adjusted as appropriate depending on the breakdown-voltage specifications, for example.

A current spreading layer (CSL) 19 of the first conductivity-type (n-type) having a higher impurity concentration than the drift layer 12 is deposited on the top surface side of the drift layer 12 in the active part 1 illustrated on the right side of FIG. 2. The current spreading layer 19 is an epitaxially-grown layer including SiC such as 4H-SiC, for example. The current spreading layer 19 has an impurity concentration in a range of about 5×10¹⁶ cm⁻³ or greater and 5×10¹⁷ cm⁻³ or less, for example. The silicon carbide semiconductor device does not necessarily include the current spreading layer 19, and the drift layer 12 may be arranged to further extend toward a region corresponding to the current spreading layer 19 when not provided.

A base region 14 of a second conductivity-type (p-type) is deposited on the top surface side of the current spreading layer 19. The base region 14 is an epitaxially-grown layer including SiC such as 4H-SiC, for example. The base region 14 may be a region obtained such that p-type impurity ions are implanted into the current spreading layer 19. The base region 14 has an impurity concentration in a range of about 1×10¹⁶ cm⁻³ or greater and 1×10¹⁸ cm⁻³ or less, for example.

A first main region (a source region) 15 of the first conductivity-type (n⁺-type) having a higher impurity concentration than the drift layer 12 is selectively deposited on the top surface side of the base region 14. The source region 15 is a region including SiC obtained such that n-type impurity ions are implanted into the base region 14, for example. The source region 15 may include either 3C—SiC or 4H—SiC. The source region 15 has an impurity concentration in a range of about 1×10¹⁹ cm⁻³ or greater and 1×10²² cm⁻³ or less, for example.

A base contact region 16 of p⁺-type having a higher impurity concentration than the base region 14 is selectively deposited on the top surface side of the base region 14. The side surface of the base contact region 16 is in contact with the source region 15. The base contact region 16 is a region including SiC obtained such that p-type impurity ions are implanted into the base region 14, for example. The base contact region 16 may include either 3C—SiC or 4H—SiC. The base contact region 16 has an impurity concentration in a range of about 5×10¹⁸ cm⁻³ or greater and 5×10²⁰ cm⁻³ or less, for example.

The trench 9 is arranged from the top surface of the source region 15 in the normal direction with respect to the top surface of the source region 15 (in the depth direction) to penetrate the source region 15 and the base region 14. The bottom surface of the trench 9 reaches the current spreading layer 19. The bottom surface of the trench 9, when the current spreading layer 19 is not provided, reaches the drift layer 12. The trench 9 has a width of about one micrometer or smaller, for example. The source region 15 and the base region 14 are in contact with the side surface of the trench 9 on the right side. The trench 9 may have a planar pattern extending in a stripe state in the backside direction and the front direction in the sheet of FIG. 2, or may have a dot-like planar pattern.

Although not illustrated in FIG. 2, a plurality of trenches common to the trench 9 are arranged in the active part 1. While the base region 14 and the source region 15 are provided only toward the side surface of the trench 9 on the right side since the trench 9 is located on the outermost side of the active part 1, the base region and the source region may be provided toward the side surfaces on both sides of the respective trenches located on the inside of the outermost trench 9.

A gate insulating film 17 is provided along the bottom surface and the side surfaces on both sides of the trench 9. A gate electrode 18 is buried inside the trench 9 with the gate insulating film 17 interposed. The gate insulating film 17 and the gate electrode 18 implement a trench-gate insulated gate electrode structure (17, 18).

The gate insulating film 17 as used herein can be a single film of a silicon oxide film (a SiO₂ film), a silicon oxynitride (SiON) film, a strontium oxide (SrO) film, a silicon nitride (Si₃N₄) film, an aluminum oxide (Al₂O₃) film, a magnesium oxide (MgO) film, an yttrium oxide (Y₂O₃) film, a hafnium oxide (HfO₂) film, a zirconium oxide (ZrO₂) film, a tantalum oxide (Ta₂O₅) film, or a bismuth oxide (Bi₂O₃) film, or a composite film including some of the above films stacked on one another. The gate electrode 18 can be made of a polysilicon layer (a doped polysilicon layer) heavily doped with p-type or n-type impurity ions or made from refractory metal such as titanium (Ti), tungsten (W), or nickel (Ni), for example.

A gate bottom protection region 13 of the second conductivity-type (p⁺-type) is provided inside the current spreading layer 19 on the top surface side of the drift layer 12. The gate bottom protection region 13 may be provided inside the drift layer 12 when the current spreading layer 19 is not provided. The gate bottom protection region 13 is in contact with the bottom surface of the trench 9. The gate bottom protection region 13 is not necessarily in contact with the bottom surface of the trench 9. The gate bottom protection region 13 is a region including SiC such as 4H—SiC obtained such that p-type impurity ions are implanted into the current spreading layer 19, for example. The gate bottom protection region 13 has an impurity concentration in a range of about 1×10¹⁷ cm⁻³ or greater and 1×10¹⁹ cm⁻³ or less, for example. The gate bottom protection region 13 may be electrically connected to the base region 14.

An interlayer insulating film 28 is deposited on the top surface side of the gate electrode 18. The interlayer insulating film 28 is a single-layer film, such as a borophosphosilicate glass film (a BPSG film), a phosphosilicate glass film (a PSG film), a non-doped silicon oxide film without containing phosphorus (P) or boron (B) which is referred to as a non-doped silicate glass (NSG) film, a borosilicate glass film (a BSG film), or a silicon nitride (Si₃N₄) film, or a stacked-layer film including the above films stacked on one another. The interlayer insulating film 28 is provided with an opening (a contact hole) 28a to which at least a part of the respective top surfaces of the source region 15 and the base contact region 16 is exposed.

A first main electrode (a source electrode) (20, 21, 22) is provided to cover the interlayer insulating film 28 and the respective top surfaces of the source region 15 and the base contact region 16 exposed to the contact hole 28a of the interlayer insulating film 28. The source electrode (20, 21, 22) includes a silicide layer 20, a barrier metal layer 21, and a source wiring layer 22 stacked in this order from the bottom side.

The silicide layer 20 includes silicide such as nickel silicide (NiSiₓ), for example. The silicide layer 20 is provided partly in a region directly in contact with the source region 15 and the base contact region 16. The part of the silicide layer 20 in contact with the source region 15 and the base contact region 16 is not necessarily provided when the source region 15 and the base contact region 16 each include 3C—SiC since an ohmic contact at a low resistance can be achieved. In such a case, the source region 15 and the base contact region 16 may be directly in contact with the barrier metal layer 21 instead.

The barrier metal layer 21 includes titanium nitride (TiN), titanium (Ti), or metal having a stacked-layer structure of TiN/Ti including Ti as a lower layer, for example. The source wiring layer 22 is provided separately from a gate wiring electrode (not illustrated) electrically connected to the gate electrode 18. The source wiring layer 22 includes metal such as aluminum (Al) and copper (Cu), or an alloy such as an aluminum-silicon (Al—Si) alloy and an aluminum-copper (Al—Cu) alloy, for example.

A second main region (a drain region) 11 of the first conductivity-type (n⁺-type) having a higher impurity concentration than the drift layer 12 is deposited on the bottom surface side of the drift layer 12. The drain region 11 is made of a semiconductor substrate (a SiC substrate) including SiC such as 4H—SiC, for example. The drain region 11 has an impurity concentration in a range of about 1×10¹⁸ cm⁻³ or greater and 3×10²⁰ cm⁻³ or less, for example. The drain region 11 has a thickness in a range of about 30 micrometers or greater and 500 micrometers or smaller, for example. A dislocation conversion layer or a recombination promotion layer having a higher impurity concentration than the drift layer 12 and having a lower impurity concentration than the drain region 11 may be provided as an n-type buffer layer between the drift layer 12 and the drain region 11.

A second main electrode (a drain electrode) 23 is deposited on the bottom surface side of the drain region 11. The drain electrode 23 can be a single-layer film including gold (Au), or a metallic film including titanium (Ti), nickel (Ni), and Au stacked in this order from the drain region 11 side, and may be further provided with a metallic film including molybdenum (Mo) or tungsten (W) as the lowermost layer, for example. A silicide layer including nickel silicide (NiSiₓ) or the like for ohmic contact may be provided between the drain region 11 and the drain electrode 23.

A stepped part (a mesa groove) 6 is provided in the edge termination part 2 illustrated on the left side of FIG. 2. The provision of the stepped part 6 leads the top surface of the semiconductor base-body 10 in the edge termination part 2 to have one step lower than the top surface in each of the active part 1 and the intermediate part 3. The p-type voltage blocking region 24 is located on the top surface side of the drift layer 12 in the edge termination part 2. The voltage blocking region 24 is arranged into a ring-shaped (frame-like) state so as to surround the respective circumferences of the active part 1 and the intermediate part 3.

The voltage blocking region 24 has a junction termination extension (JTE) structure, for example. The voltage blocking region 24 may include a plurality of regions having different impurity concentrations varied from the inner side toward the outer side of the semiconductor base-body 10. The voltage blocking region 24 is not limited to the JTE structure, and may include a plurality of p-type guard rings arranged in a concentric manner so as to interpose the drift layer 12. Although not illustrated in FIG. 2, a channel stopper that is a semiconductor region of n⁺-type or p⁺-type may be arranged in a concentric manner on the top surface side of the drift layer 12 at the end part of the outer circumference of the edge termination part 2.

A field insulating film 27 is deposited on the respective top surfaces of the drift layer 12 and the voltage blocking region 24 in the edge termination part 2. The field insulating film 27 is an insulating film such as a film of local oxidation of silicon (a LOCOS film), for example. The interlayer insulating film 28 is deposited on the top surface of the field insulating film 27 with the gate insulating film 17 interposed. The interlayer insulating film 28 may be a single-layer film of a silicon oxide film (a SiO₂ film) without containing impurity ions referred to as a NSG film, a phosphosilicate glass film (a PSG film), a borosilicate glass film (a BSG film), a borophosphosilicate glass film (a BPSG film), or a silicon nitride film (a Si₃N₄ film), or a composite film including some of the above films combined together.

A semiconductor region (25, 26) of p-type is provided on the top surface side of the drift layer 12 in the intermediate part 3 illustrated in the middle of FIG. 2. The semiconductor region (25, 26) is arranged into a ring-shaped (frame-like) state so as to surround the circumference of the active part 1. The semiconductor region (25, 26) is described in detail below. The insulating film (17, 27) is deposited on the top surface of the semiconductor region (25, 26). The insulating film (17, 27) includes the field insulating film 27 provided in contact with a part of the top surface of the semiconductor region (25, 26), and the gate insulating film 17 provided in contact with another part of the top surface of the semiconductor region (25, 26). The field insulating film 27 continuously extends from the edge termination part 2 toward the intermediate part 3. The gate insulating film 17 is continuously provided from the inside of the trench 9 in the active part 1 toward the edge termination part 2 so as to extend toward the respective top surfaces of the semiconductor region (25, 26) and the field insulating film 27. The gate insulating film 17 has a smaller thickness than the field insulating film 27. The thickness of the gate insulating film 17 is set in a range of about 50 nanometers or greater and 150 nanometers or smaller, for example. The thickness of the field insulating film 27 is set in a range of about 400 nanometers or greater and 1000 nanometers or smaller, for example.

A wiring layer (a gate runner) 31 is deposited on the respective top surfaces of the gate insulating film 17 and the field insulating film 27 in the intermediate part 3. The wiring layer 31 is arranged along the top surface of the part in which the gate insulating film 17 and the field insulating film 27 having different thicknesses are stacked to further extend to the top surface of the single gate insulating film 17 so as to have a stepped part 31a. The wiring layer 31 may be deposited on the insulating films having the same thickness so as to have a flat surface with no stepped part provided. The wiring layer 31 includes polysilicon heavily doped with p-type or n-type impurity ions. The wiring layer 31 is located at a position overlapping with at least a part of the semiconductor region (25, 26) in the depth direction.

The interlayer insulating film 28 is deposited on the top surface of the wiring layer 31. The interlayer insulating film 28 continuously extends from the edge termination part 2 to the intermediate part 3. The interlayer insulating film 28 is provided with an opening (a contact hole) 28b. The gate pad 30 is provided on the top surface of the interlayer insulating film 28 with the barrier metal layer 21 interposed. The wiring layer 31 is in contact with the barrier metal layer 21 via the contact hole 28b. The gate pad 30 is electrically connected to the gate electrode 18 via the barrier metal layer 21 and the wiring layer 31. The barrier metal layer 21 under the gate pad 30 is not necessarily provided in this embodiment.

The following are specific explanations regarding the p-type semiconductor region (25, 26) under the gate pad 30. The semiconductor region (25, 26) has a two-layer structure including a first region 25 including 4H—SiC (a 4H structure) as a lower layer provided on the top surface side of the drift layer 12 and a second region 26 including 3C—SiC (a 3C structure) as an upper layer provided on the top surface side of the first region 25. The first region 25 and the second region 26 are provided into a ring-shaped (frame-like) state so as to surround the circumference of the active part 1. While FIG. 2 illustrates the case in which the second region 26 is deposited on the entire top surface of the first region 25, the second region 26 may be provided selectively in a part of the top surface of the first region 25.

The bottom surface of the first region 25 is in contact with the top surface of the drift layer 12. The side surface on the outer side (the outer circumferential surface) of the first region 25 is in contact with the side surface on the inner side (the inner circumferential surface) of the voltage blocking region 24. While FIG. 2 illustrates the case in which the first region 25 has substantially the same depth as the voltage blocking region 24, the depth of the first region 25 may be either deeper than or shallower than the depth of the voltage blocking region 24.

The side surface on the inner side (the inner circumferential surface) of the first region 25 is in contact with the side surface of the trench 9 located at the outermost circumference of the active part 1 and the gate bottom protection region 13. The side surface on the inner side of the first region 25 may be separated from the gate bottom protection region 13. While the present embodiment is illustrated with the case in which the first region 25 has substantially the same depth as the gate bottom protection region 13, the depth of the first region 25 may be either deeper than or shallower than the depth of the gate bottom protection region 13.

The first region 25 may include a plurality of regions having different impurity concentrations in the depth direction. The part of the first region 25 located at the same depth as the base region 14 in the active part 1 may be formed simultaneously with the base region 14 and may have the same impurity concentration as the base region 14. The part of the first region 25 located at the same depth as the gate bottom protection region 13 in the active part 1 may be formed simultaneously with the gate bottom protection region 13 and may have the same impurity concentration as the gate bottom protection region 13.

The first region 25 has a thickness in a range of about one micrometer or greater and two micrometers or smaller, for example. The first region 25 is a region having fewer crystal defects than the second region 26 and hardly taking over the crystal defects in the second region 26. The first region 25 includes 4H—SiC. The first region 25 is a region mainly including 4H—SiC without including 3C—SiC. The proportion of 4H—SiC included in the first region 25 is in a range of about 90% or greater and 100% or smaller, for example. The first region 25 may further have an amorphous structure and include a small amount of 3C—SiC other than 4H—SiC, for example. The impurity concentration of the first region 25 is in a range of about 1×10¹⁶ cm⁻³ or greater and 1×10¹⁹ cm⁻³ or less, for example. The first region 25 includes aluminum (Al) or boron (B) as p-type impurity ions, for example.

The bottom surface of the second region 26 is located at a position shallower than the top surface of the voltage blocking region 24 provided in the edge termination part 2. The side surface on the outer side (the outer circumferential surface) of the second region 26 is not in contact with the side surface on the inner side (the inner circumferential surface) of the voltage blocking region 24, since the stepped part 6 is provided between the edge termination part 2 and the intermediate part 3. The side surface on the inner side (the inner circumferential surface) of the second region 26 is in contact with the side surface of the trench 9 located at the outermost circumference of the active part 1.

The top surface of the second region 26 on the inner side is in contact with the source electrode (20, 21, 22) via an opening (a contact hole) 28c provided in the interlayer insulating film 28. The second region 26, when including 3C—SiC that has a narrower bandgap than 4H—SiC, can be led to be in ohmic contact with the source electrode (20, 21, 22) at a low resistance. The part in which the second region 26 is in contact with the source electrode (20, 21, 22) is thus not provided with the silicide layer 20, so as to avoid a separation of the silicide layer 20 from the part in contact with the second region 26. The top surface of the second region 26 is in contact with the barrier metal layer 21.

The second region 26 may be formed simultaneously with the base contact region 16 in the active part 1, and may have the same impurity concentration as the base contact region 16. The second region 26 has a thickness in a range of about 0.1 micrometers or greater and 0.3 micrometers or smaller, for example, which is about 1/20 or greater and ⅕ or smaller of the thickness of the first region 25. The second region 26 is a region including 3C—SiC. The proportion of 3C—SiC included in the second region 26 is in a range of 10% or greater and 100% or smaller, for example. The second region 26 may be a mixed-crystal region including 3C—SiC and 4H—SiC. The second region 26 may further have an amorphous structure and include 4H—SiC other than 3C—SiC, for example.

The impurity concentration of the second region 26 is either higher than or substantially the same as that of the first region 25. The impurity concentration of the second region 26 is in a range of about 1×10¹⁹ cm⁻³ or greater and 1×10²² cm⁻³ or less, for example. The second region 26 includes aluminum (Al) or boron (B) as p-type impurity ions, for example. The second region 26 may include an inactive element such as argon (Ar) or helium (He), for example. Since 3C—SiC has a higher ionization energy of p-type impurity ions such as Al than 4H—SiC, 3C—SiC has a smaller number of holes and has a higher resistance. The second region 26 thus has a higher specific resistance than the first region 25.

The first region 25 and the second region 26 can be formed independently of each other such that some conditions such as the element to be implanted, the temperature during the ion implantation, the dose (the impurity concentration), and the activation temperature are changed for each of the first region 25 and the second region 26.

The first region 25 including 4H—SiC is formed such that p-type impurity ions are implanted to 4H—SiC at a high temperature (for example, at about 500° C.) at an impurity concentration (a dose) that can sufficiently avoid destruction of the structure of 4H—SiC. The dose upon the ion implantation is set to about less than 2×10¹⁵ cm⁻², for example. The activation annealing is then executed at a temperature of about 1600° C. or higher and 1900° C. or lower, so as to form the first region 25 while keeping the structure of 4H—SiC.

The second region 26 including 3C—SiC is formed, for example, such that p-type impurity ions or an inactive element is implanted to 4H—SiC at a room temperature at a high impurity concentration (a high dose) so as to destroy 4H—SiC to form an amorphous structure by use of damage during the ion implantation. The total dose of the impurity ions to be implanted including the dose of the impurity ions implanted to the first region 25 described above is set to about 2×10¹⁵ cm⁻² or greater, for example. Upon the ion implantation for the second region 26, an inactive element such as argon (Ar) or helium (He) may be implanted instead of the p-type impurity ions. When the inactive element is used for the ion implantation, the p-type impurity ions are implanted only to the first region 25, and the first region 25 and the second region 26 thus have substantially the same impurity concentration.

The activation annealing is then executed at a temperature of about 1600° C. or higher and 1900° C. or lower to lead the amorphous structure to turn to 3C—SiC when recrystallized, so as to form the second region 26 including 3C—SiC.

The respective crystal structures of the first region 25 and the second region 26 can be measured (observed) such that a ratio of the areas of the crystal structures on the surfaces is measured by use of a field-emission scanning electron microscope (FE-SEM) and electron backscatter diffraction (EBSD). The present embodiment executed the measurement, as an example, such that samples were prepared under the common conditions of the element of the impurity ions to be implanted, the dose (the impurity concentration), and the activation temperature, while the different temperatures were used upon the ion implantation that were 500° C. and a room temperature (25° C.) so as to be measured by use of the FE-SEM and the EBSD. The proportion of 4H—SIC on the surface in the sample obtained at 500° C. was 100%. The proportion of 4H—SiC on the surface in the sample obtained at the room temperature was 86%, while the proportion of 3C—SiC was 14%.

The silicon carbide semiconductor device according to the first embodiment during the switching operation applies a positive voltage to the drain electrode 23 while using the source electrode (20, 21, 22) as a ground potential, and causes an inversion layer (a channel) to be formed in the base region 14 toward the side surface of the trench 9 so as to be in the ON-state when a positive voltage of a threshold or greater is applied to the gate electrode 18. In the ON-state, a current flows from the drain electrode 23 toward the source electrode (20, 21, 22) through the drain region 11, the drift layer 12, the current spreading layer 19, the inversion layer of the base region 14, and the source region 15. When the voltage applied to the gate electrode 18 is smaller than the threshold, the silicon carbide semiconductor device is led to be the OFF-state since no inversion layer is formed in the base region 14, and no current flows from the drain electrode 23 toward the source electrode (20, 21, 22).

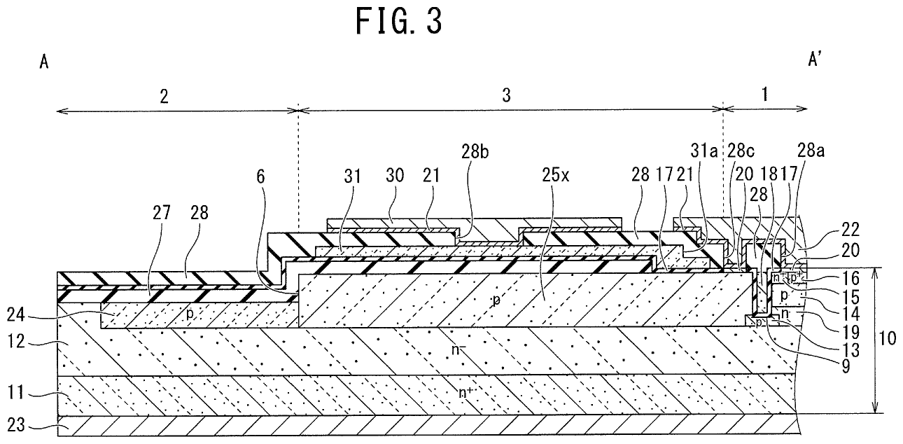

FIG. 3 is a schematic cross-sectional view illustrating a silicon carbide semiconductor device of a comparative example. As illustrated in FIG. 3, the silicon carbide semiconductor device of the comparative example differs from the silicon carbide semiconductor device according to the first embodiment illustrated in FIG. 2 in that a p-type semiconductor region 25x made of a single layer of 4H—SiC is provided under the gate pad 30 in the intermediate part 3. The silicon carbide semiconductor device of the comparative example further differs from the silicon carbide semiconductor device according to the first embodiment in that the silicide layer 20 is provided at a part at which the source electrode (20, 21, 22) is in contact with the semiconductor region 25x. The other configurations of the silicon carbide semiconductor device of the comparative example are substantially the same as those of the silicon carbide semiconductor device according to the first embodiment, and overlapping explanations are not repeated below.

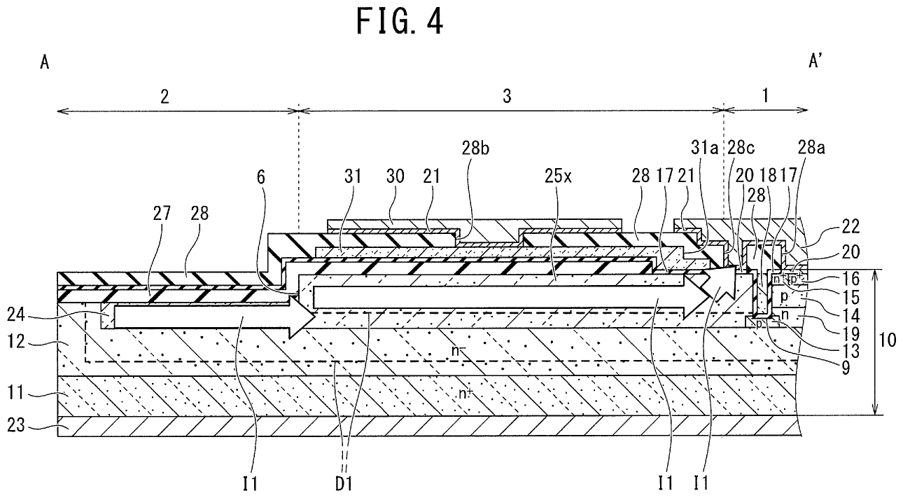

The silicon carbide semiconductor device of the comparative example in the OFF-operation during switching applies a source potential of about zero volts to the source electrode (20, 21, 22), applies a gate potential of about −3 volts to the gate pad 30 and the wiring layer 31, and applies a drain potential that is substantially the same as a power-supply voltage to the drain electrode 23, for example. A depletion layer D1 as schematically indicated by the broken line in FIG. 4 thus expands from a p-n junction between the n-type drift layer 12 and each of the p-type voltage blocking region 24 and the p-type semiconductor region 25x. A displacement current I1 is then caused due to a hole in association with a change (dV/dt) of a source-drain voltage Vds. The displacement current I1 can be given by the following formula:

$$I 1 = C \times d V / dt \qquad ( 1 )$$

where C is a capacity of the depletion layer D1.

The displacement current I1 flows from the voltage blocking region 24 toward the semiconductor region 25x, and is extracted through the source electrode (20, 21, 22) in the active part 1 in contact with the top surface of the semiconductor region 25x. A potential V1 of the semiconductor region 25x rises up due to a resistance of the semiconductor region 25x when the displacement current I1 flows. The resistance R of the semiconductor region 25x can be given by the following formula (2);

$$R ∝ L \times R ◻ \qquad ( 2 )$$

where R_{□} is a sheet resistance of the semiconductor region 25x, and Lis a length from the outer circumference to the inner circumference of the semiconductor region 25x.

The potential V1 of the semiconductor region 25x can be given by the following formula (3):

$$V 1 = IR \qquad ( 3 )$$

This configuration increases a difference between the potential V1 of the semiconductor region 25x and the gate potential of the wiring layer 31, which may cause insulation damage to the gate insulating film 17 and the field insulating film 27 implementing the insulating film (17, 27) located between the semiconductor region 25x and the wiring layer 31. The insulation damage tends to be caused particularly at a part only provided with the gate insulating film 17 without the field insulating film 27 stacked together.

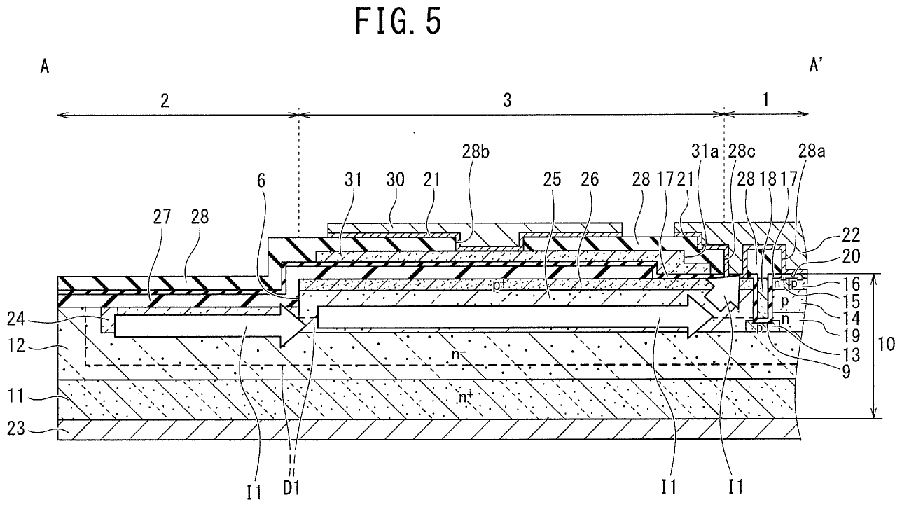

In contrast, the configuration of the silicon carbide semiconductor device according to the first embodiment in the OFF-operation during switching leads the depletion layer D1 to expand from the p-n junction between the n-type drift layer 12 and each of the p-type voltage blocking region 24 and the p-type semiconductor region (25, 26), as schematically illustrated in FIG. 5. The displacement current I1 is then caused due to the hole in association with the change (dV/dt) of the source-drain voltage Vds. The displacement current I1 flows from the voltage blocking region 24 toward the semiconductor region (25, 26), and is extracted through the source electrode (20, 21, 22) in the active part 1 in contact with the top surface of the semiconductor region (25, 26).

The silicon carbide semiconductor device according to the first embodiment has the configuration in which the p-type semiconductor region (25, 26) under the gate pad 30 has the two-layer structure implemented by the first region 25 including 4H—SiC as a lower layer and the second region 26 including 3C—SiC as an upper layer. Since the second region 26 has a higher specific resistance than the first region 25, the path of the displacement current I1 is provided on the first region 25 side as a lower layer. The current path of the displacement current I1 is thus separated away from the gate insulating film 17 and the field insulating film 27 implementing the insulating film (17, 27), so as to reduce the electric field applied to the gate insulating film 17 and the field insulating film 27. This can avoid damage to the gate insulating film 17 and the field insulating film 27, improving the reliability accordingly.

### Second Embodiment

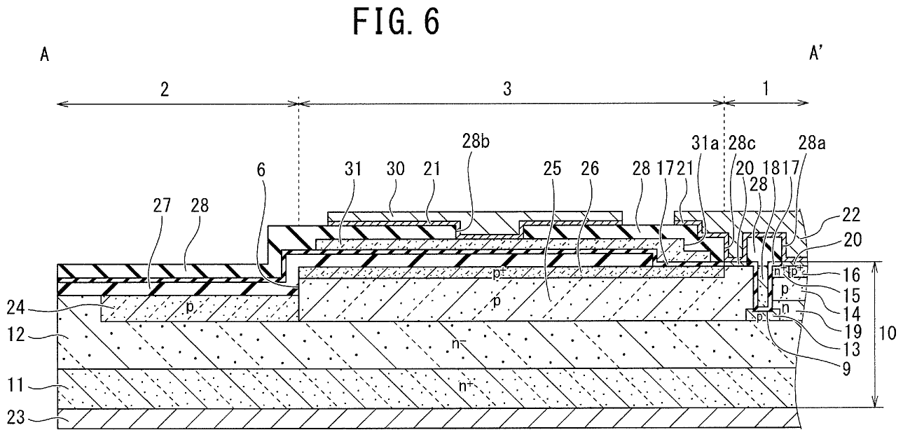

A silicon carbide semiconductor device according to a second embodiment differs from the silicon carbide semiconductor device according to the first embodiment illustrated in FIG. 2 in that the second region 26 that is the upper layer of the p-type semiconductor region (25, 26) is selectively provided in a part of the top surface of the first region 25 that is the lower layer, as illustrated in FIG. 6.

The second region 26 is provided in a part of the first region 25 on the top surface side overlapping with the wiring layer 31. The second region 26 is not provided in the part in contact with the source electrode (20, 21, 22) in the active part 1. The part of the top surface of the first region 25 not provided with the second region 26 is in contact with the source electrode (20, 21, 22). The part of the source electrode (20, 21, 22) in contact with the first region 25 is provided with the silicide layer 20. The other configurations of the silicon carbide semiconductor device according to the second embodiment are substantially the same as those of the silicon carbide semiconductor device according to the first embodiment illustrated in FIG. 2, and overlapping explanations are not repeated below.

The silicon carbide semiconductor device according to the second embodiment, which has the configuration in which the p-type semiconductor region (25, 26) under the gate pad 30 has the two-layer structure implemented by the first region 25 including 4H—SiC as a lower layer and the second region 26 including 3C—SiC as an upper layer, leads the displacement current caused upon the OFF-operation during switching to flow toward the first region 25 that is the lower layer, so as to keep away from the gate insulating film 17 and the field insulating film 27. This configuration can reduce the electric field applied to the gate insulating film 17 and the field insulating film 27, so as to avoid damage to the gate insulating film 17 and the field insulating film 27 accordingly.

Further, the silicon carbide semiconductor device according to the second embodiment has the configuration in which the first region 25 having a lower specific resistance than the second region 26 is in contact with the source electrode (20, 21, 22), so as to decrease the resistance in the current path of the displacement current in the part from which the displacement current is extracted to the source electrode (20, 21, 22).

### Third Embodiment

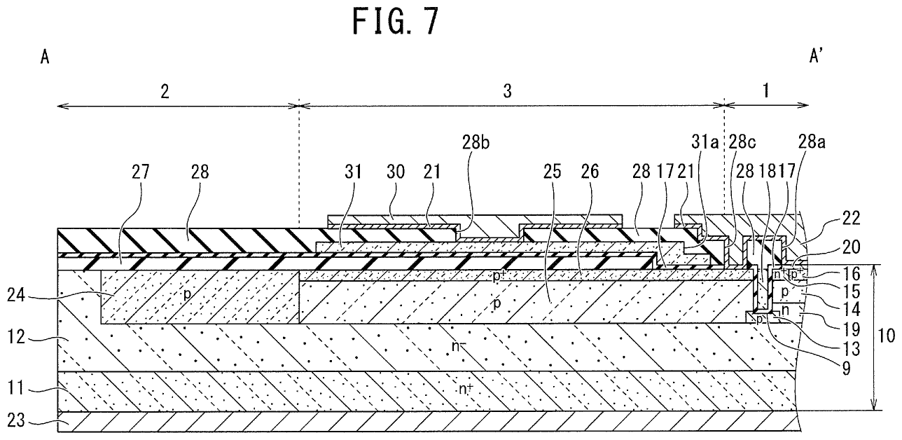

A silicon carbide semiconductor device according to a third embodiment differs from the silicon carbide semiconductor device according to the first embodiment illustrated in FIG. 2 in not having the stepped part (the mesa groove) in the edge termination part 2, as illustrated in FIG. 7.

Since the mesa groove is not provided, the height of the top surface of the semiconductor base-body 10 in the edge termination part 2 conforms to the height of the top surface of the semiconductor base-body 10 in each of the active part 1 and the intermediate part 3 so that the top surface of the semiconductor base-body 10 is entirely flat. The side surface on the inner side (the inner circumferential surface) of the voltage blocking region 24 in the edge termination part 2 is in contact with the side surface on the outer side (the outer circumferential surface) of each of the first region 25 and the second region 26 in the intermediate part 3. The other configurations of the silicon carbide semiconductor device according to the third embodiment are substantially the same as those of the silicon carbide semiconductor device according to the first embodiment illustrated in FIG. 2, and overlapping explanations are not repeated below.

The silicon carbide semiconductor device according to the third embodiment, which has the configuration in which the p-type semiconductor region (25, 26) under the gate pad 30 has the two-layer structure implemented by the first region 25 including 4H—SiC as a lower layer and the second region 26 including 3C—SiC as an upper layer, leads the displacement current caused upon the OFF-operation during switching to flow toward the first region 25 that is the lower layer, so as to keep away from the gate insulating film 17 and the field insulating film 27. This configuration can reduce the electric field applied to the gate insulating film 17 and the field insulating film 27, so as to avoid damage to the gate insulating film 17 and the field insulating film 27 accordingly.

### Fourth Embodiment

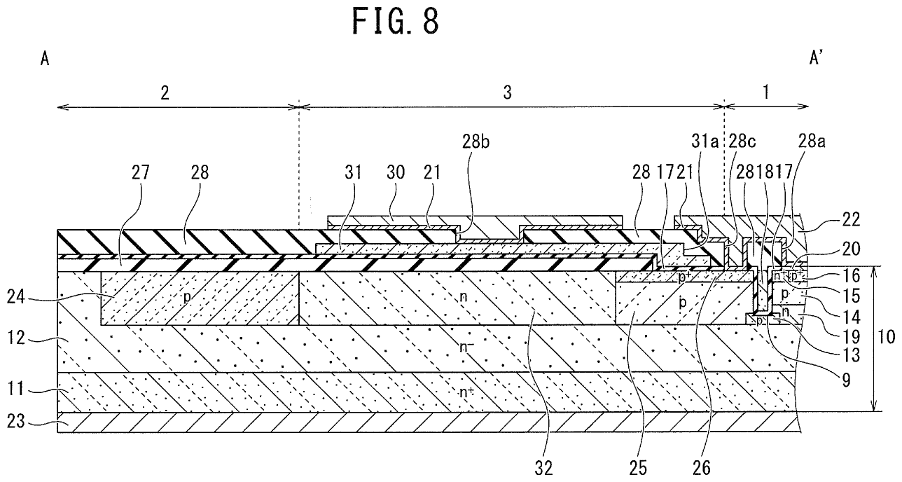

A silicon carbide semiconductor device according to a fourth embodiment has a configuration common to that of the silicon carbide semiconductor device according to the third embodiment illustrated in FIG. 7 in not having the stepped part (the mesa groove) in the edge termination part 2, but differs from the silicon carbide semiconductor device according to the third embodiment in including a semiconductor region 32 of n-type in the intermediate part 3 between the p-type semiconductor region (25, 26) and the voltage blocking region 24 in the edge termination part 2, as illustrated in FIG. 8. The semiconductor region 32 is made of an epitaxially-grown layer including SiC such as 4H—SiC. The semiconductor region 32 may have either a higher impurity concentration or a lower impurity concentration than the drift layer 12, or may have substantially the same impurity concentration as the drift layer 12.

The semiconductor region 32 is arranged into a ring-shaped (frame-like) state so as to surround the respective side surfaces on the outer side (the outer circumferential surfaces) of the first region 25 and the second region 26. The side surface on the inner side (the inner circumferential surface) of the semiconductor region 32 is in contact with the respective side surfaces on the outer side (the outer circumferential surfaces) of the first region 25 and the second region 26. The side surface on the outer side (the outer circumferential surface) of the semiconductor region 32 is in contact with the side surface on the inner side (the inner circumferential surface) of the voltage blocking region 24. While FIG. 8 illustrates the case in which the depth of the semiconductor region 32 substantially conforms to the depth of the first region 25, the depth of the semiconductor region 32 may be either greater than or shallower than the depth of the first region 25. Similarly, while the depth of the semiconductor region 32 substantially conforms to the depth of the voltage blocking region 24, the depth of the semiconductor region 32 may be either greater than or shallower than the depth of the voltage blocking region 24. In addition, the semiconductor region 32 may be the drift layer 12.

The first region 25 is located at a position overlapping with a part of the wiring layer 31 in the depth direction. The second region 26 only needs to be provided at least in a part on the top surface side of the first region 25 at which the wiring layer 31 overlaps with the gate insulating film 17. The other configurations of the silicon carbide semiconductor device according to the fourth embodiment are substantially the same as those of the silicon carbide semiconductor device according to the first embodiment illustrated in FIG. 2, and overlapping explanations are not repeated below.

The silicon carbide semiconductor device according to the fourth embodiment, which has the configuration in which the p-type semiconductor region (25, 26) under the gate pad 30 has the two-layer structure implemented by the first region 25 including 4H—SiC as a lower layer and the second region 26 including 3C—SiC as an upper layer, leads the displacement current caused upon the OFF-operation during switching to flow toward the first region 25 that is the lower layer, so as to keep away from the gate insulating film 17 and the field insulating film 27. This configuration can reduce the electric field applied to the gate insulating film 17 and the field insulating film 27, so as to avoid damage to the gate insulating film 17 and the field insulating film 27 accordingly.

### Other Embodiments

As described above, the invention has been described according to the first to fourth embodiments, but it should not be understood that the description and drawings implementing a portion of this disclosure limit the invention. Various alternative embodiments of the present invention, examples, and operational techniques will be apparent to those skilled in the art from this disclosure.

For example, while the first to fourth embodiments have been illustrated above with the semiconductor device using the trench gate MOSFET as the active element included in the active part 1, the present invention can be applied to a planar gate MOSFET. The present invention can also be applied to an insulated gate bipolar transistor (IGBT) with a configuration including a p⁺-type collector region, instead of the n⁺-type drain region 11 of the MOSFET. The present invention can further be applied to a reverse-conducting insulated gate bipolar transistor (RC-IGBT) or a reverse-blocking insulated gate bipolar transistor (RB-IGBT), instead of the simple IGBT.

The respective configurations disclosed in the first to fourth embodiments can be combined together as appropriate without contradiction with each other. For example, the silicon carbide semiconductor device according to the second embodiment illustrated in FIG. 6 may have a configuration in which the top surface of the semiconductor base-body 10 is entirely flat without being provided with the stepped part (the mesa groove) in the edge termination part 2, as in the case of the silicon carbide semiconductor device according to the third embodiment illustrated in FIG. 7.

Alternatively, the silicon carbide semiconductor device according to the second embodiment illustrated in FIG. 6 may have a configuration in which the n-type semiconductor region 32 is provided in the intermediate part 3 between the p-type semiconductor region (25, 26) and the voltage blocking region 24 in the edge termination part 2, as in the case of the silicon carbide semiconductor device according to the fourth embodiment illustrated in FIG. 8.

Alternatively, the silicon carbide semiconductor device according to the third embodiment illustrated in FIG. 7 may have a configuration in which the n-type semiconductor region 32 is provided in the intermediate part 3 between the p-type semiconductor region (25, 26) and the voltage blocking region 24 in the edge termination part 2, as in the case of the silicon carbide semiconductor device according to the fourth embodiment illustrated in FIG. 8.

Alternatively, the silicon carbide semiconductor device according to the fourth embodiment illustrated in FIG. 8 may have a configuration provided with the stepped part (the mesa groove) in the edge termination part 2, as in the case of the silicon carbide semiconductor device according to the first embodiment illustrated in FIG. 2.

As described above, the invention includes various embodiments of the present invention and the like not described herein. Therefore, the scope of the present invention is defined only by the technical features specifying the present invention, which are prescribed by claims, the words and terms in the claims shall be reasonably construed from the subject matters recited in the present specification.

What is claimed is:

1. A silicon carbide semiconductor device comprising:
a drift layer of a first conductivity-type including silicon carbide and provided from an active part including an active element to an edge termination part located at a circumference of the active part;
a semiconductor region of a second conductivity-type including silicon carbide and provided on a top surface side of the drift layer in an intermediate part interposed between the active part and the edge termination part;
a first insulating film provided on a top surface of the semiconductor region;
a wiring layer provided on a top surface of the first insulating film;
a second insulating film provided on a top surface of the wiring layer; and
a gate pad provided on a top surface of the second insulating film so as to be electrically connected to the wiring layer via an opening provided in the second insulating film,
wherein the semiconductor region includes
a first region having a 4H structure overlapping with at least a part of the wiring layer in a depth direction, and
a second region having a 3C structure provided on a top surface side of the first region.

2. The silicon carbide semiconductor device of claim 1, further comprising a voltage blocking region of the second conductivity-type including silicon carbide provided on the top surface side of the drift layer in the edge termination part.

3. The silicon carbide semiconductor device of claim 2, wherein:
the edge termination part is provided with a stepped part;
a height of a top surface of the voltage blocking region is smaller than a height of a top surface of the second region; and
a side surface of the voltage blocking region is in contact with a side surface of the first region.

4. The silicon carbide semiconductor device of claim 2, wherein:
a height of a top surface of the voltage blocking region conforms to a height of a top surface of the second region; and
a side surface of the voltage blocking region is in contact with a side surface of each of the second region and the first region.

5. The silicon carbide semiconductor device of claim 2, further comprising a semiconductor region of the first conductivity-type including silicon carbide and interposed between the voltage blocking region and each of the second region and the first region.

6. The silicon carbide semiconductor device of claim 1, further comprising a main electrode to which a main region of the active element is electrically connected,
wherein the second region and the first region extend from the intermediate part to the active part, and
a top surface of the second region is in contact with the main electrode.

7. The silicon carbide semiconductor device of claim 6, wherein the top surface of the second region is in contact with a barrier metal layer of the main electrode.

8. The silicon carbide semiconductor device of claim 1, further comprising a main electrode to which a main region of the active element is electrically connected,
wherein the first region extends from the intermediate part to the active part, and
the top surface of the first region is in contact with the main electrode.

9. The silicon carbide semiconductor device of claim 8, wherein the top surface of the first region is in contact with a silicide layer of the main electrode.

10. The silicon carbide semiconductor device of claim 1, wherein the second region is selectively provided at a part overlapping with the wiring layer on the top surface side of the first region.

11. The silicon carbide semiconductor device of claim 1, wherein the second region is provided along the entire top surface side of the first region.
